(19) United States
(12) Patent Application Publication
(10) Pub. No.: US 2024/0313176 A1
(43) Pub. Date: Sep. 19, 2024

(54) DISPLAY SYSTEM

(71) Applicant: SONY GROUP CORPORATION, TOKYO (JP)

(72) Inventors: AKIRA OHMAE, TOKYO (JP); KOTARO SHIMA, TOKYO (JP); NORIYUKI HIRAI, TOKYO (JP); YUTAKA SUGAWARA, TOKYO (JP); SHIN AKASAKA, TOKYO (JP); SEIJI KASAHARA, TOKYO (JP)

(21) Appl. No.: 18/576,110

(22) PCT Filed: Feb. 22, 2022
(86) PCT No.: PCT/JP2022/007142

§ 371 Date: Jan. 3, 2024

(30) Foreign Application Priority Data
Jul. 16, 2021 (JP) 2021-117555

(51) Int. Cl. H01L 33/58; H01L 25/075

(52) U.S. Cl. CPC H01L 33/58; H01L 25/0753

(57) ABSTRACT

The present disclosure relates to a display system that enables video representation of higher quality. A display includes a plurality of light sources and a light absorption layer that forms a display surface and absorbs external light applied to the display surface. An opening through which light from the light sources is emitted toward a side of the display surface is formed in the light absorption layer. The technology according to the present disclosure may be applied to, for example, a tiling display.

### TECHNICAL FIELD

The present disclosure relates to a display system, and particularly relates to a display system that enables video representation of higher quality.

### BACKGROUND ART

There has been known a method of forming a large-screen display device by combining a plurality of small display panels each including a light emitting element serving as a light source as a pixel. Such a display device is called a tiling display or the like.

Some of the tiling displays are configured such that an interval forming member that forms an interval between display panels is disposed to improve accuracy of the interval between adjacent display panels and to improve display quality, as disclosed in Patent Document 1, for example.

### CITATION LIST

### Patent Document

Patent Document 1: Japanese Patent Application Laid-Open No. 2015-194515

### SUMMARY OF THE INVENTION

### Problems to be Solved by the Invention

According to the existing display technologies, such as a single flat display or curved surface display, a smartphone, and the like as well as a tiling display, it has not been easy to achieve both suppression of light reflection on the surface and maintenance of high contrast. Thus, there has been a possibility that video representation quality is deteriorated depending on the display installation environment.

The present disclosure has been conceived in view of such circumstances, and aims to achieve video representation of higher quality.

### Solutions to Problems

A display system according to the present disclosure is a display system that includes a display including a plurality of light sources and a light absorption layer that forms a display surface and absorbs external light applied to the display surface, in which an opening through which light from the light sources is emitted toward a side of the display surface is formed in the light absorption layer.

In the present disclosure, the plurality of light sources and the light absorption layer that forms the display surface and absorbs external light applied to the display surface are provided in the display, and the opening through which light from the light sources is emitted toward the side of the display surface is formed in the light absorption layer.

### BRIEF DESCRIPTION OF DRAWINGS

FIG. 1 is a diagram illustrating a configuration example of a display system to which the technology according to the present disclosure is applied.

FIG. 2 is a diagram illustrating a configuration example of a video wall controller and a display unit.

FIG. 3 is a diagram for explaining an outline of a structure of the display unit.

FIG. 4 is a diagram illustrating an example of an opening formed in a light absorption layer.

FIG. 5 is a cross-sectional view illustrating a configuration example of the display unit.

FIG. 6 is a diagram illustrating exemplary light emitting elements.

FIG. 7 is a diagram illustrating another example of the opening.

FIG. 8 is a diagram illustrating still another example of the opening.

FIG. 9 is a diagram illustrating yet another example of the opening.

FIG. 10 is a diagram illustrating exemplary curved surface displays.

FIG. 11 is a diagram for explaining an outline of the display unit having flexibility/extensibility.

FIG. 12 is a cross-sectional view illustrating a configuration example of the display unit.

FIG. 13 is a top view illustrating a configuration example of the display unit.

FIG. 14 is a cross-sectional view illustrating another configuration example of the display unit.

FIG. 15 is a cross-sectional view illustrating still another configuration example of the display unit.

FIG. 16 is a diagram illustrating a configuration example of the display system for virtual production.

FIG. 17 is a diagram illustrating a configuration example of the display system for virtual production.

### MODE FOR CARRYING OUT THE INVENTION

Hereinafter, modes for carrying out the present disclosure (hereinafter referred to as embodiments) will be described. Note that the description will be given in the following order.
1. Problems in existing display technology
2. Display system to which technology according to present disclosure may be applied
3. Structure having fine light source and light absorption layer
4. Application to curved surface display
5. Application to display system for virtual production

### <1. Problems in Existing Display Technology>

According to the existing display technology, it has not been easy to achieve both suppression of light reflection on the surface and maintenance of high contrast.

Specifically, in a case where a display surface is made glossy, the surrounding environment is reflected due to surface reflection while high contrast may be maintained. Furthermore, in a case where the display surface is matted, the contrast of display video is lowered due to scattering reflection while the surface reflection may be suppressed. Thus, there has been a possibility that video representation quality is deteriorated depending on the display installation environment.

In view of the above, according to a display system to which the technology according to the present disclosure is applied, it becomes possible to achieve both suppression of light reflection on the display surface and maintenance of high contrast, and to achieve video representation of higher quality.

Note that the display system to which the technology according to the present disclosure is applied is assumed to include various display devices having a display surface, such as a single flat display or curved surface display, a smartphone, a smart watch, a gaming display, a cave automatic virtual environment (CAVE) display, a head mounted display (HMD), a goggle display, a tiling display, a display unit constituting a tiling display, and the like.

<2. Display System to which Technology According to Present Disclosure May be Applied>

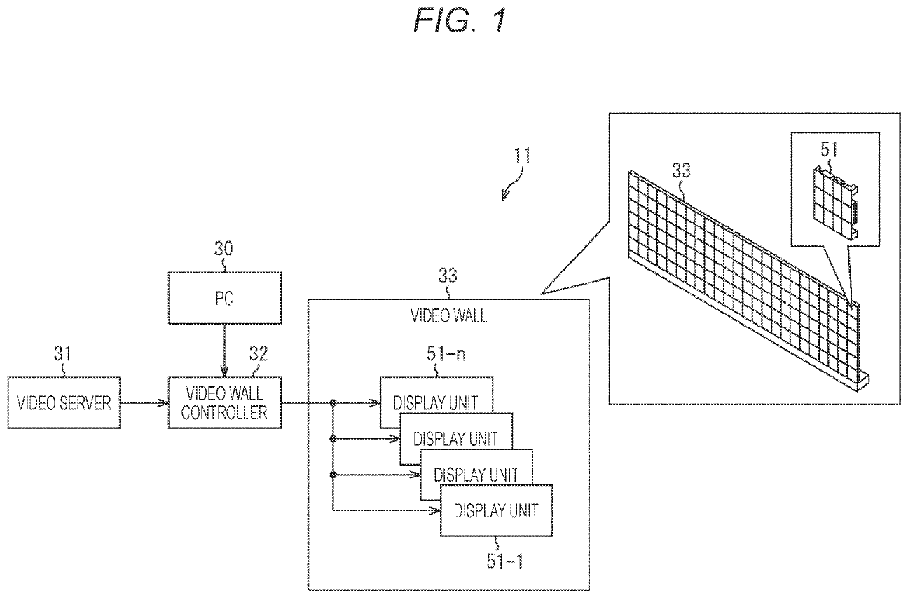

FIG. 1 illustrates a configuration example of the display system including a tiling display as an exemplary display system to which the technology according to the present disclosure may be applied.

A display system 11 in FIG. 1 includes a plurality of tiled display units, and displays video content on a large display.

The display system 11 includes a personal computer (PC) 30, a video server 31, a video wall controller 32, and a video wall 33.

The PC 30 is a general-purpose computer, which receives an operation input made by a user and supplies a command corresponding to the operation content to the video wall controller 32.

The video server 31 includes, for example, a server computer or the like, and supplies data of a video signal of video content or the like to the video wall controller 32.

The video wall controller 32 operates in response to the command supplied from the PC 30, and distributes the data including the video signal of the video content to display units 51-1 to 51-n included in the video wall 33 to cause them to display the data.

Hereinafter, the display units 51-1 to 51-n will be simply referred to as a display unit 51 in a case where they are not required to be individually distinguished from each other.

As illustrated in the upper right part of FIG. 1, the video wall 33 includes the tiled display units 51-1 to 51-n in which pixels including light emitting diodes (LEDs) are arranged in an array. In the video wall 33, images displayed on the individual display units 51 are tiled and combined, thereby displaying one piece of image on the entire video wall 33.

Note that the video wall controller 32 and the video wall 33 may be integrally configured, or may be integrated into a display device.

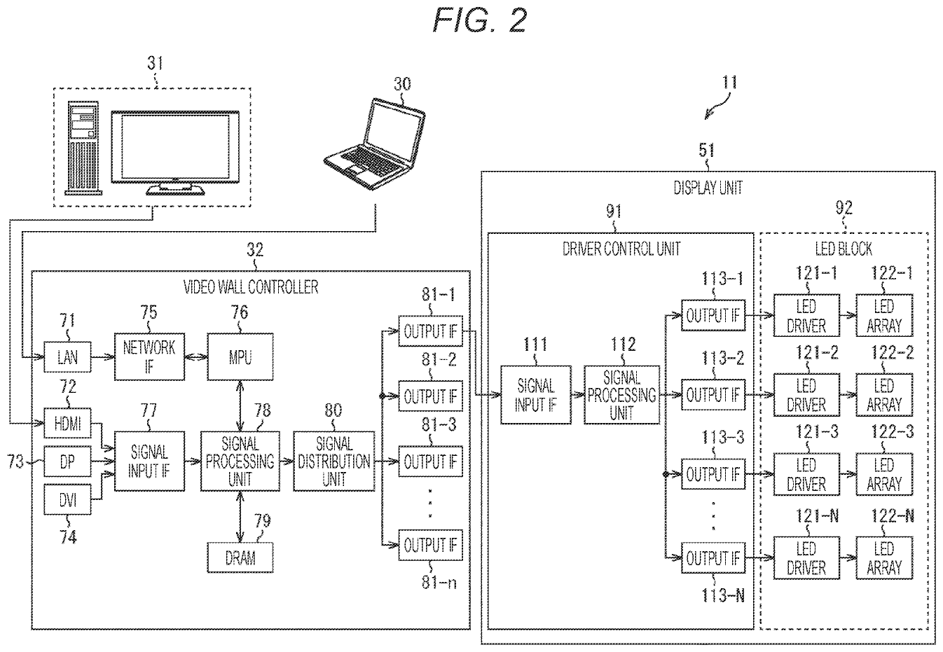

Next, detailed configuration examples of the video wall controller 32 and the display unit 51 will be described with reference to FIG. 2.

The video wall controller 32 includes individual terminals of a LAN terminal 71, an HDMI (registered trademark) terminal 72, a DP terminal 73, and a DVI terminal 74. Furthermore, the video wall controller 32 includes a network interface (IF) 75, an MPU 76, a signal input IF 77, a signal processing unit 78, a DRAM 79, a signal distribution unit 80, and output IFs 81-1 to 81-n.

The local area network (LAN) terminal 71 is, for example, a connection terminal such as a LAN cable. The LAN terminal 71 implements communication with the PC 30 that supplies a control command or the like corresponding to operation content of the user to the video wall controller 32, and supplies the input control command or the like to the MPU 76 via the network IF 75.

The LAN terminal 71 may have a configuration adapted to physical connection with a wired LAN cable, or may have a configuration adapted to connection with what is called a wireless LAN implemented by wireless communication.

The micro processor unit (MPU) 76 receives the input of the control command supplied from the PC 30 via the LAN terminal 71 and the network IF 75, and supplies a control signal corresponding to the control command to the signal processing unit 78.

Each of the high definition multimedia interface (HDMI) terminal 72, the display port (DP) terminal 73, and the digital visual interface (DVI) terminal 74 is an input terminal for data including the video signal. The HDMI terminal 72, the DP terminal 73, and the DVI terminal 74 are connected to a server computer that functions as the video server 31, and supply the data including the video signal to the signal processing unit 78 via the signal input IF 77. Note that the video wall controller 32 may include an input terminal based on another standard, such as a serial digital interface (SDI) terminal.

Although FIG. 2 illustrates an exemplary case where the video server 31 and the HDMI terminal 72 are connected, the HDMI terminal 72, the DP terminal 73, and the DVI terminal 74 have only different standards and basically have similar functions, and thus any one of them may be selected and connected as necessary.

The signal processing unit 78 adjusts color temperature, contrast, brightness, and the like of the data including the video signal supplied via the signal input IF 77 on the basis of the control signal supplied from the MPU 76, and supplies the data to the signal distribution unit 80. At this time, as necessary, the signal processing unit 78 develops the data including the video signal using the connected dynamic random access memory (DRAM) 79, executes signal processing based on the control signal, and supplies a result of the signal processing to the signal distribution unit 80.

The signal distribution unit 80 distributes the data including the video signal, which has been subject to the signal processing and supplied from the signal processing unit 78, and individually distributes the data to the display units 51-1 to 51-n via the output IFs 81-1 to 81-n.

The display unit 51 includes a driver control unit 91 and an LED block 92.

The driver control unit 91 supplies, to a plurality of LED drivers 121-1 to 121-N included in the LED block 92, the data including the video signal for controlling light emission of LEDs included in LED arrays 122-1 to 122-N.

The driver control unit 91 includes a signal input IF 111, a signal processing unit 112, and output IFs 113-1 to 113-N.

The signal input IF 111 receives the input of the data of the video signal supplied from the video wall controller 32, and supplies the data to the signal processing unit 112.

The signal processing unit 112 corrects the color and luminance of each of the display units 51 on the basis of the data of the video signal supplied from the signal input IF 111, and generates data for setting light emission intensity of each of the LEDs included in the LED arrays 122-1 to 122-N. The generated data is distributed to the LED drivers 121-1 to 121-N of the LED block 92 via the output IFs 113-1 to 113-N.

The LED block 92 includes the LED drivers 121-1 to 121-N and the LED arrays 122-1 to 122-N.

Hereinafter, the LED drivers 121-1 to 121-N will be simply referred to as an LED driver 121 in a case where they are not required to be individually distinguished from each other, and the LED arrays 122-1 to 122-N will be simply referred to as an LED array 122 in a case where they are not required to be individually distinguished from each other.

The LED driver 121 performs pulse width modulation (PWM) control on the light emission of the LED arranged in the corresponding LED array 122 on the basis of the data for setting the light emission intensity of the LED supplied from the driver control unit 91.

Hereinafter, a structure of the display unit 51 will be described.

### <3. Structure Having Fine Light Source and Light Absorption Layer>

### (Display Unit Structure)

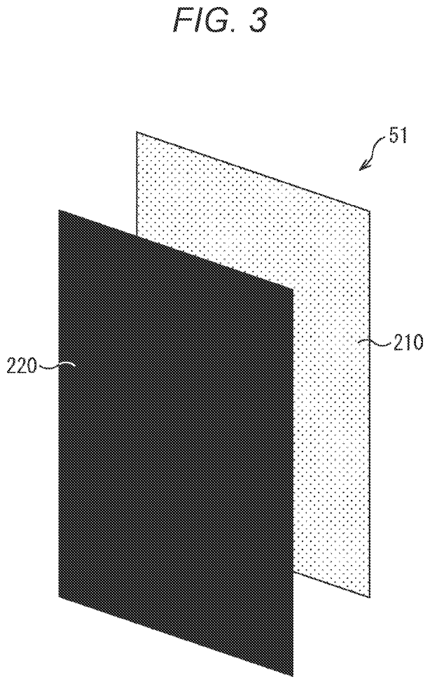

An outline of the structure of the display unit 51 will be described with reference to FIG. 3.

FIG. 3 illustrates a structure of a display, which is a configuration related to display of the display unit 51. The display of the display unit 51 (hereinafter simply referred to as display unit 51) has a structure and a function of displaying an image on a flat display surface, and includes a light source substrate 210 and a light absorption layer 220 laminated on the light source substrate 210.

The light source substrate 210 includes fine RGB LEDs serving as a plurality of light sources arranged in an array on the entire front surface of the substrate. The LEDs arranged on the light source substrate 210 are microminiature LEDs in micrometer units, and are also called micro-LED or the like. Each of such LEDs (light sources) forms a pixel in the display unit 51.

The light absorption layer 220 forms the display surface of the display unit 51, and has a function of absorbing external light applied to the display surface. The light absorption layer 220 includes a black light-absorptive material. The light absorption layer 220 includes, for example, a black material such as resin, carbon nanotube, urethane foam, or the like. The light absorption layer 220 is only required to have a property of absorbing light, and may have a structure for optical confinement, such as scales of deep-sea fishes that absorb and do not reflect light in the deep sea.

While the display unit 51 is an element of a minimum unit included in the video wall 33 as a display device here, the display unit 51 itself may include a plurality of tiled display modules. According to such a configuration, it becomes possible to replace the display panel in display module units, and the like. Furthermore, in this case, the light absorption layer 220 may be provided not only in units of the display units 51 but also in units of the display modules.

In the light absorption layer 220, openings through which the light of the LEDs (light sources) arranged on the light source substrate 210 is emitted toward the display surface side are formed.

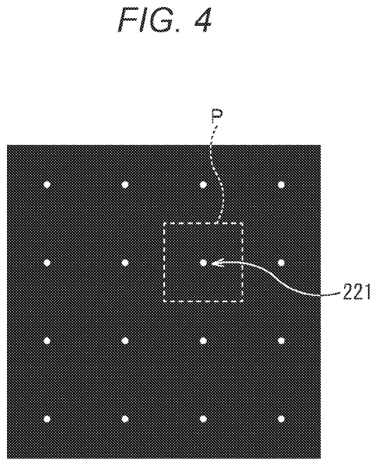

FIG. 4 is a diagram illustrating an example of the openings formed in the light absorption layer 220.

Openings 221 are formed at positions corresponding to the LEDs arranged in an array on the light source substrate 210. More specifically, one opening 221 is formed for one LED included in one pixel P. The opening 221 is finely formed corresponding to the LED arranged on the light source substrate 210, and a ratio occupied by the opening 221 in one pixel P is very small.

Note that, while the opening 221 is formed in a circular shape in top view in the example of FIG. 4, it is not limited to this, and may be formed in another shape such as a rectangular shape.

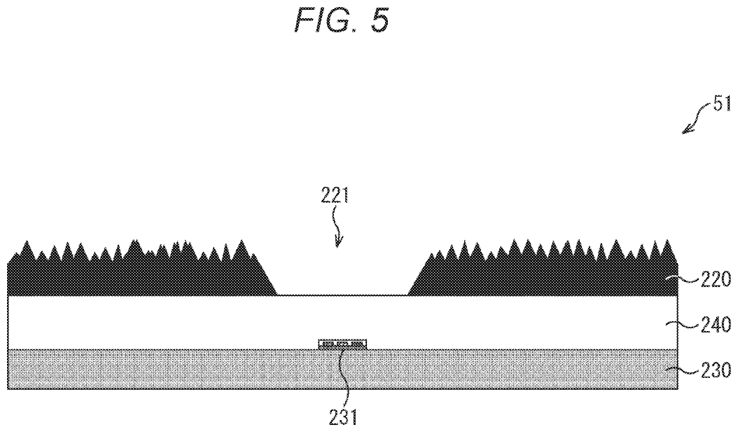

FIG. 5 is a cross-sectional view illustrating a configuration example of the display unit 51.

FIG. 5 illustrates a cross-sectional view corresponding to one pixel P in the display unit 51.

In the display, a light emitting element 231 serving as a light source is provided on a wiring substrate 230. The light emitting element 231 includes the RGB micro-LED described above disposed on a drive circuit. That is, the light emitting element 231 forms a pixel including RGB subpixels.

A planarization layer 240 is formed on the wiring substrate 230. The planarization layer 240 is formed to include a transparent photosensitive material.

The light absorption layer 220 is formed on the planarization layer 240 via an adhesive layer (not illustrated). The light absorption layer 220 has an uneven structure on the display surface side. The uneven structure is a structure that suppresses reflection of external light, and the light absorption layer 220 is enabled to absorb the external light applied to the display surface by the uneven structure and the black light-absorptive material.

In the light absorption layer 220, the opening 221 is formed at the position corresponding to the light emitting element 231. The light absorption layer 220 is capable of emitting the light of the light emitting element 231 toward the display surface side through the opening 221.

While the light emitting element 231 is provided on a layer (lower layer side) different from the light absorption layer 220 in which the opening 221 is formed in FIG. 5, it may be provided on the same layer as the light absorption layer 220. In this case, the light emitting element 231 is disposed in the opening of the opening 221 in the cross-sectional view.

Furthermore, while the cross section of the opening 221 is formed in a tapered shape from the display surface side toward the light emitting element 231 (side of wiring substrate 230) in FIG. 5, it is not limited to this, and may be formed to have the same diameter from the display surface side toward the light emitting element 231.

According to the configuration above, in the light absorption layer 220 that absorbs the external light applied to the display surface of the display unit 51, the opening 221 that emits the light of the light emitting element 231 toward the display surface side is formed. With this arrangement, it becomes possible to achieve both suppression of light reflection on the display surface and maintenance of high contrast, and to achieve video representation of higher quality.

### (Exemplary Light Emitting Element)

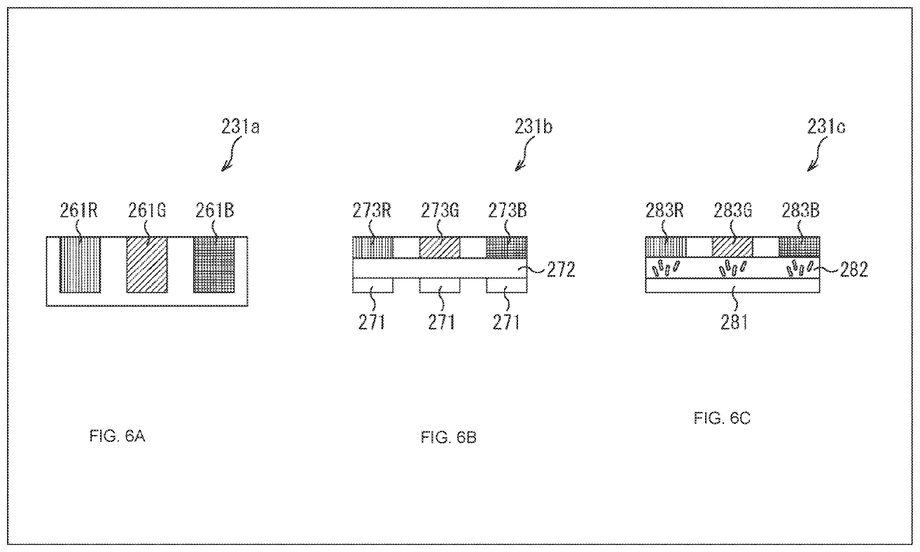

An example of the light emitting element 231 will be described with reference to FIG. 6.

A of FIG. 6 illustrates, as an example of the light emitting element 231, an LED element 231a including the RGB micro-LED described above. In the LED element 231a, each of red, green, and blue LEDs 261R, 261G, and 261B constituting the RGB subpixels emits light by itself. According to the LED element 231a, it becomes possible to achieve a display having a simple structure, high light extraction efficiency, and extremely little viewing angle restriction.

B of FIG. 6 illustrates an organic electro-luminescence (EL) element 231b as an example of the light emitting element 231. In the organic EL element 231b, light from white organic EL 271 formed for the individual subpixels is emitted from red, green, and blue color filters 273R, 273G, and 273B via a transparent conductive film 272. According to the organic EL element 231b, the RGB subpixels may be caused to emit light independently. Note that the organic EL element may be called an organic light-emitting diode (OLED) element.

In the organic EL element 231b, an organic EL element that emits light in each color of RGB by itself may be used instead of the white organic EL 271. In a case where the light emitting element 231 includes the organic EL elements, it is considered that the light emitting elements 231 are arranged side by side on the wiring substrate 230 at intervals narrower than those in a case of including the LED elements. In that case, the pixel at the position corresponding to the opening 221 may be caused to emit light.

C of FIG. 6 illustrates a liquid crystal element 231c as an example of the light emitting element 231. In the liquid crystal element 231c, light of white LED 281 that emits light as backlight passes through a liquid crystal shutter 282, and is emitted from red, green, and blue color filters 283R, 283G, and 283B. According to the liquid crystal element 231c, a transmission amount of the backlight is controlled by opening and closing of the liquid crystal shutter 282, whereby the RGB subpixels may be caused to emit light. Also in a case where the light emitting element 231 includes the liquid crystal elements, it is considered that the light emitting elements 231 are arranged side by side on the wiring substrate 230 at intervals narrower than those in the case of including the LED elements. In that case, the pixel at the position corresponding to the opening 221 may be caused to emit light.

### (Exemplary Opening)

While it has been described that one opening 221 is formed for one light source included in one pixel P in the description above, it is not limited to this, and one opening may be formed for two or more light sources.

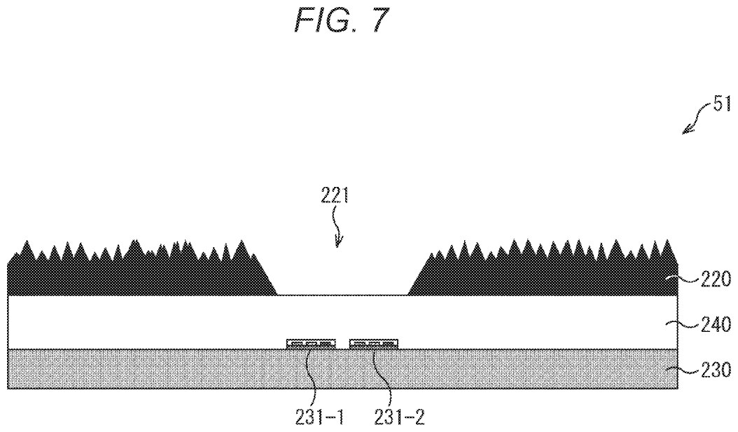

For example, as illustrated in FIG. 7, one opening 221 may be formed for two or more (two in the example of FIG. 7) light emitting elements 231-1 and 231-2.

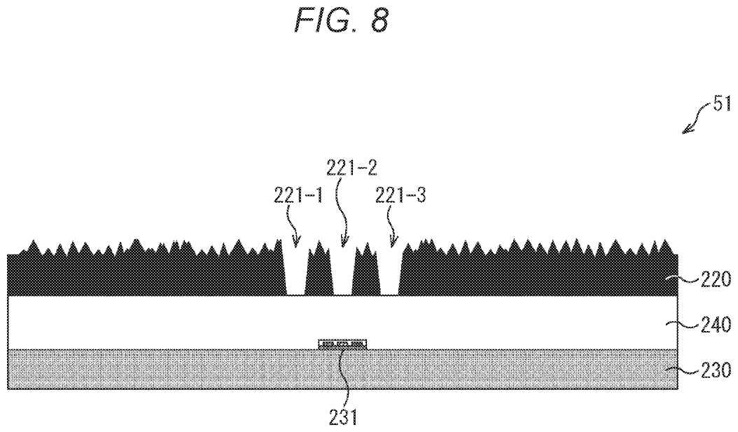

Furthermore, as illustrated in FIG. 8, a plurality of (three in the example of FIG. 8) openings 221-1, 221-2, and 221-3 may be formed for one light emitting element 231.

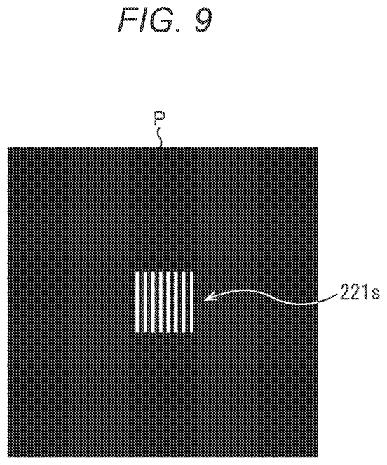

Moreover, as illustrated in FIG. 9, an opening 221s including a plurality of slits like a polarization element may be formed for a light source included in one pixel P.

### <4. Application to Curved Surface Display>

### (Exemplary Curved Surface Display)

The display system to which the technology according to the present disclosure is applied includes a curved surface display having a curved display surface in addition to a display having a flat display surface like the display unit 51 described above.

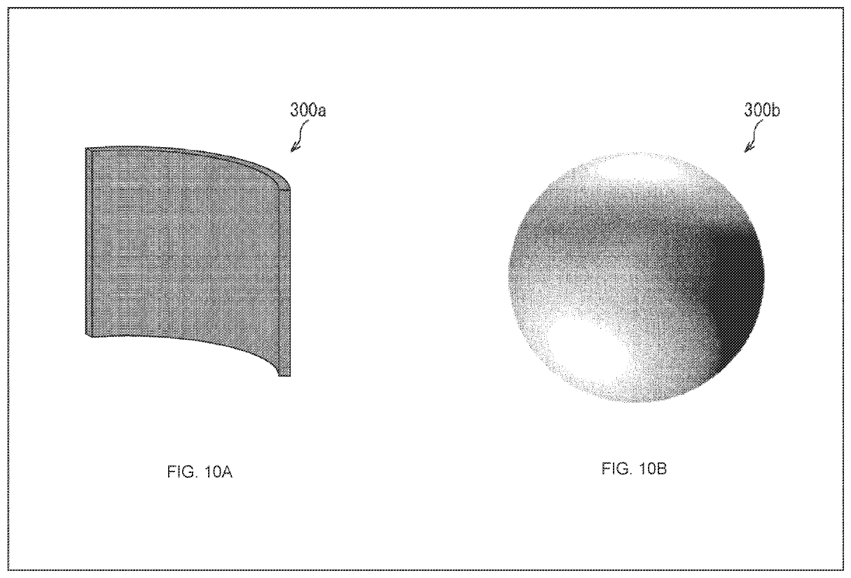

For example, a cylindrical display 300a illustrated in A of FIG. 10 or a spherical display 300b illustrated in B of FIG. 10 may be configured by combining a plurality of the display units 51 described above.

In the cylindrical display 300a, while a display surface is formed on the concave surface side, it may be formed on the convex surface side. In the spherical display 300b, while a display surface is formed on the front surface side (convex surface side) of the sphere, it may be formed on the back surface side (concave surface side). Furthermore, the spherical display 300b may be configured in a hemispherical shape instead of the perfect sphere as illustrated in FIG. 10.

Even in such a curved surface display, the light absorption layer is formed on the curved display surface, and it becomes possible to achieve both suppression of light reflection on the display surface and maintenance of high contrast. Moreover, in a case where the concave surface side of such a curved surface display is the display surface, particularly in a case where the back surface side (concave surface side) of the spherical display 300b is the display surface, it becomes possible to suppress reflection of light from a certain part of the display at another part of the display itself.

Here, in a case where the curved surface display is configured by combining a plurality of the display units 51 each having a flat display surface, a stretchable structure for absorbing distortion generated at a time of bending the display unit 51 needs to be provided in the display unit 51.

In view of the above, the display unit (display) to which the technology according to the present disclosure is applied may have at least one of flexibility or extensibility (hereinafter also referred to as flexibility/extensibility).

### (Display Unit Having Flexibility/Extensibility)

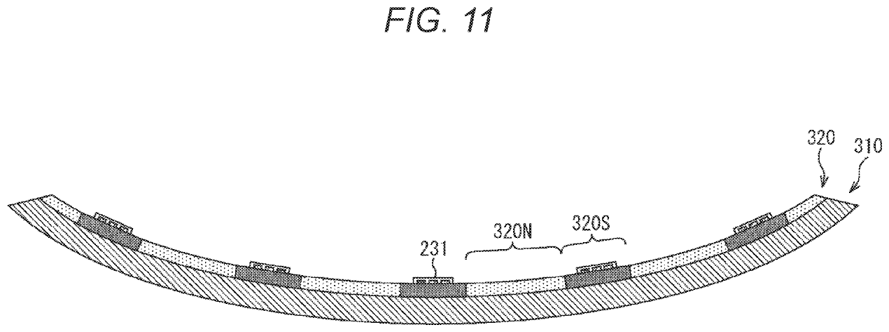

FIG. 11 is a diagram for explaining an outline of the display unit having flexibility/extensibility.

FIG. 11 illustrates, for example, a cross-sectional configuration of the curved surface display (cylindrical display 300a) illustrated in A of FIG. 10. In FIG. 11, the concave surface side (upper side in the drawing) is the display surface side of the curved surface display.

In the curved surface display illustrated in FIG. 11, a display unit 320 is provided on a chassis (frame) 310 included in the bent surface. The chassis 310 has a certain degree of rigidity, and the display unit 320 having at least one of flexibility or extensibility is provided along the bent surface thereof. Note that illustration of the light absorption layer formed on the display surface side of the display unit 320 is omitted in FIG. 11.

The display unit 320 includes non-stretchable portions 320S and stretchable portions 320N.

The non-stretchable portions 320S are arranged in an array in the display unit 320 in a case where the display unit 320 is placed on a plane. The light emitting elements 231 are arranged in the non-stretchable portions 320S.

The stretchable portions 320N constitute regions between the non-stretchable portions 320S arranged in an array, and are formed to be stretchable in the surface direction of the display surface of the display unit 320.

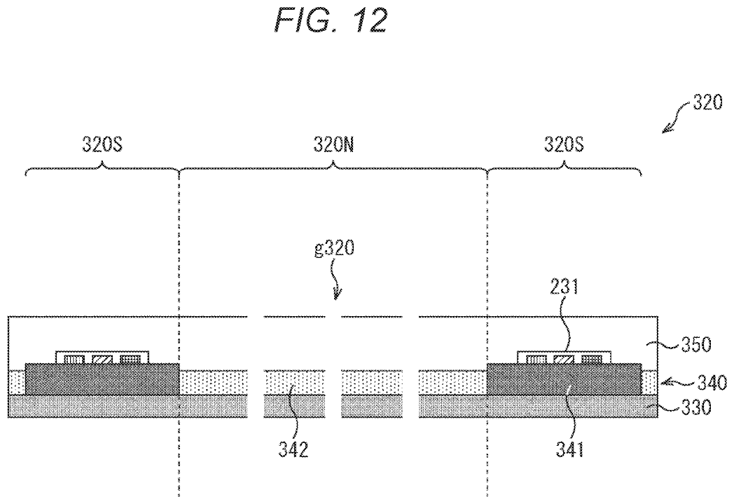

FIG. 12 is a cross-sectional view illustrating a configuration example of the display unit 320.

FIG. 12 illustrates a cross-sectional view of a portion of the display unit 320 corresponding to the two non-stretchable portions 320S and the stretchable portion 320N configured therebetween.

In the display unit 320, a flexible substrate 340 serving as a wiring substrate is provided on a reinforcing substrate 330 serving as a base.

The flexible substrate 340 includes a non-stretchable portion 341 corresponding to the non-stretchable portion 320S, and a stretchable portion 342 corresponding to the stretchable portion 320N. The light emitting elements 231 serving as light sources are arranged on the non-stretchable portion 341. The stretchable portion 342 electrically connects the non-stretchable portions 341 on which the light emitting elements 231 are arranged, and is formed to be stretchable in the surface direction of the display surface of the display unit 320.

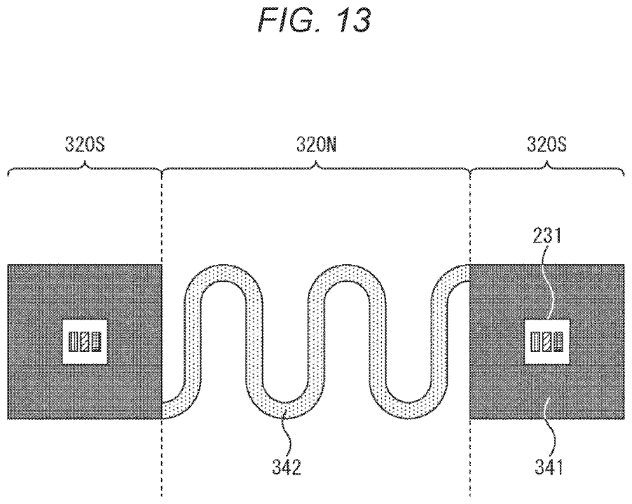

Specifically, as illustrated in the top view of FIG. 13, the stretchable portion 342 is formed as a wiring substrate having a structure in a corrugated shape for connecting adjacent stretchable portions 342.

On the flexible substrate 340, a planarization layer 350 is formed to cover the surface on which the light emitting element 231 is arranged. The planarization layer 350 is formed using a material that uniformizes the strength of the entire display unit 320 and suppresses a pitch (interval between non-stretchable portions 320S) disturbance at the time of stretching. For example, the planarization layer 350 is formed to contain a thermoplastic elastomer such as urethane, and a resin such as epoxy or acrylic. Although illustration is omitted, a light absorption layer is formed on the planarization layer 350 via an adhesive layer.

In the display unit 320, a gap g320 is formed such that the stretchable portion 320N may stretch in the surface direction of the display surface of the display unit 320. The gap g320 is formed by processing the reinforcing substrate 330 and the planarization layer 350 to avoid the stretchable portion 342 having the structure in the corrugated shape. With this arrangement, the reinforcing substrate 330 and the planarization layer 350 are made to have flexibility/extensibility.

According to the structure above, the display unit 320 has flexibility/extensibility, whereby it becomes possible to configure the curved surface display by combining a plurality of the display units 320.

### (Other Stretchable Portion Structures)

Other structures of the stretchable portion 320N of the display unit 320 will be described.

The reinforcing substrate 330 and the planarization layer 350 may have a non-adhesive region not directly adhered (bonded) to the flexible substrate 340 (stretchable portion 342) in the stretchable portion 320N (portion corresponding to the stretchable portion 342 of the flexible substrate 340).

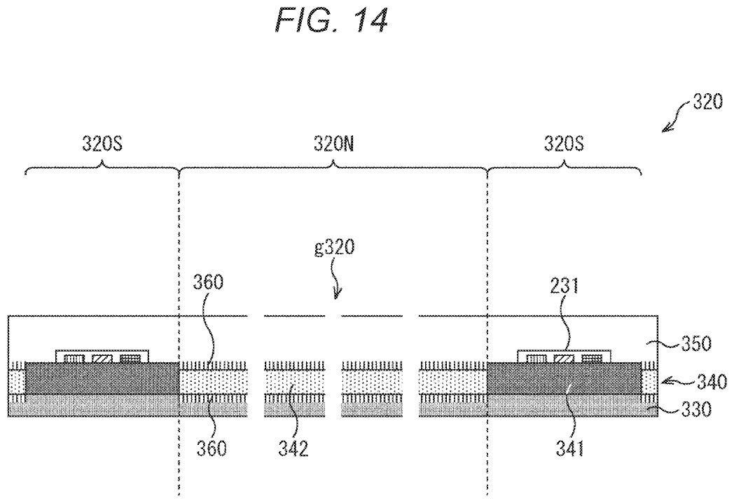

For example, as illustrated in FIG. 14, a non-adhesive layer 360 is formed between the stretchable portion 342 of the flexible substrate 340 and the reinforcing substrate 330 and between the stretchable portion 342 and the planarization layer 350. The non-adhesive layer 360 is assumed to be formed using, for example, a soft high polymeric material such as gel, a highly slidable resin, or the like.

Furthermore, a space may be formed between a portion corresponding to the stretchable portion 320N of the reinforcing substrate 330 and the planarization layer 350 and the flexible substrate 340 (stretchable portion 342).

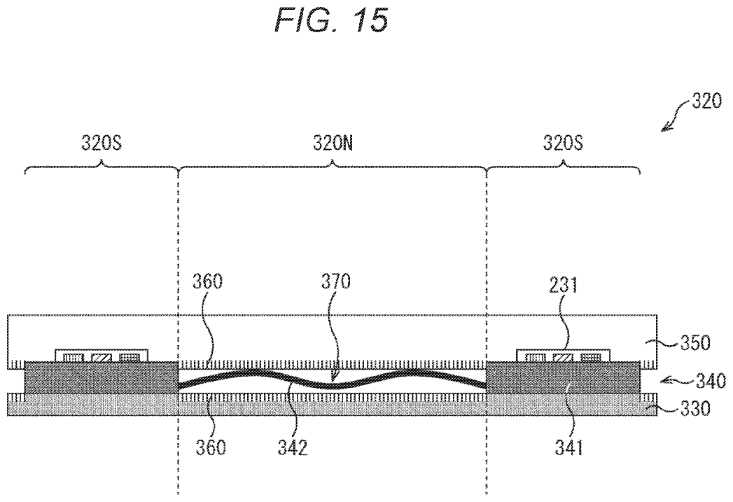

For example, as illustrated in FIG. 15, the non-adhesive layer 360 is formed between the stretchable portion 342 of the flexible substrate 340 and the reinforcing substrate 330 and between the stretchable portion 342 and the planarization layer 350, and a space 370 is formed between the non-adhesive layers 360. Here, the stretchable portion 342 of the flexible substrate 340 is assumed to be bendable in any direction.

With this arrangement, in the display unit 320, the stretchable portion 320N may be made stretchable in the surface direction of the display surface of the display unit 320 and deformable in the thickness direction of the display surface.

Furthermore, in a case where the gap g320 is formed in the stretchable portion 320N as in the display unit 320 illustrated in FIGS. 12 and 14, fine processing on the planarization layer 350 is not easy, and the area of the stretchable portion 320N needs to be relatively large. Therefore, it may not be possible to cope with the densification of the light emitting element 231 (pitch narrowing of non-stretchable portion 320S).

On the other hand, in the display unit 320 illustrated in FIG. 15, it is not necessary to form the gap g320 in the stretchable portion 320N, whereby it becomes possible to cope with the densification of the light emitting element 231 (pitch narrowing of non-stretchable portion 320S) while securing flexibility/extensibility.

### <5. Application to Display System for Virtual Production>

The technology according to the present disclosure may also be applied to a display system for virtual production.

The virtual production is a method of displaying three-dimensional computer graphics (3DCG) video on a large display as a background, arranging an actual person or object in front of the 3DCG as a subject, and performing re-imaging with a camera. In the virtual production, it is possible to obtain video as if the video is captured in a virtual space by synchronizing positional information of a camera and a focal length of a lens with 3DCG video within an imaging range of the camera.

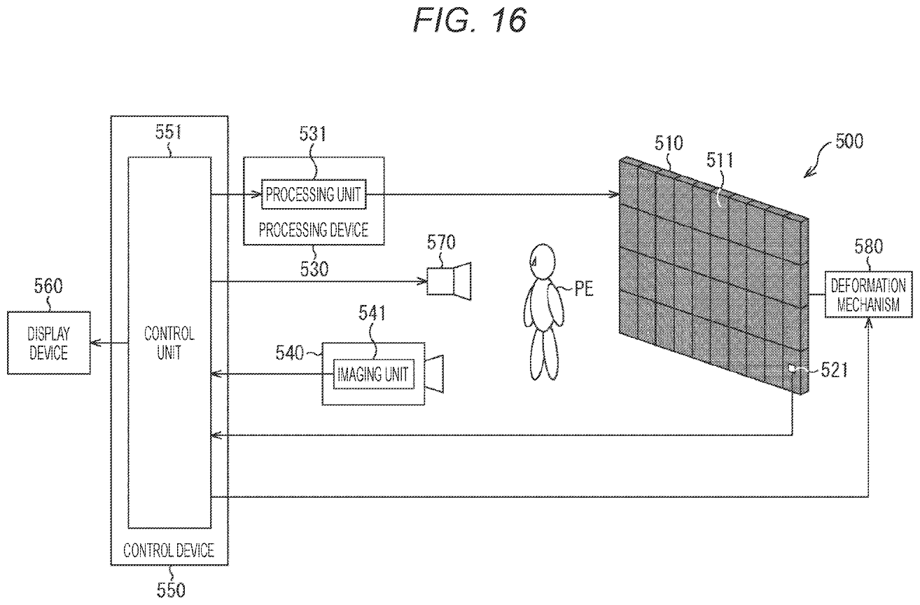

FIG. 16 is a diagram illustrating a configuration example of the display system for virtual production to which the technology according to the present disclosure is applied.

A display system 500 in FIG. 16 is installed in a photographing studio or the like for video production.

The display system 500 includes a display device 510, a processing device 530, an imaging device 540, a control device 550, a display device 560, and an illumination device 570.

The display device 510 corresponds to the video wall 33 in FIG. 1, which is a tiling display obtained by tiling a plurality of display units 511. In the display device 510, images displayed on the plurality of individual display units 511 are combined, thereby displaying one 3DCG video.

Each of the display units 511 may have at least one of flexibility or extensibility. In this case, the display unit 511 may also be provided with a sensor unit 521 that detects a physical quantity on the display surface of the display unit 511 instead of any of the light emitting elements (light sources) arranged on the non-stretchable portion described above.

The sensor unit 521 includes, for example, a distance sensor that detects a distance from an object such as a performer PE or another object located on the display surface side of the display unit 511, a luminance sensor that detects luminance of external light, a contact sensor that detects contact with the display surface of the display unit 511, and the like. Note that the sensor unit 521 may be provided outside the display unit 511.

The processing device 530 corresponds to the video wall controller 32 in FIG. 1, and includes a processing unit 531 that executes display processing of an image (3DCG video) on the plurality of display units 511 of the display device 510.

The imaging device 540 serves as a video camera, and includes an imaging unit 541 that captures an image (3DCG video) displayed on the plurality of display units 511 of the display device 510 together with the performer PE positioned in front thereof. The imaging device 540 obtains positional information of its own device, a focal length of a lens, and information indicating an imaging range of the imaging unit 541, and supplies them to the control device 550 together with the video captured by the imaging unit 541.

The control device 550 serves as a display controller that controls the entire display system 500. The control device 550 includes a control unit 551 that controls display of an image (3DCG video) on the plurality of display units 511 of the display device 510 according to the imaging range of the imaging unit 541. Specifically, the control unit 551 controls display of an image on each of the display units 511 via the processing device 530 to synchronize the positional information of the imaging device 540 and the focal length of the lens with the video within the imaging range of the imaging unit 541 on the basis of the information indicating the imaging range of the imaging unit 541.

Furthermore, the control device 550 (control unit 551) may control the display of the 3DCG video on the display device 510 on the basis of the physical quantity detected by the sensor unit 521 provided in the display unit 511.

For example, in a case where a luminance sensor is provided as the sensor unit 521, the control device 550 is enabled to adjust the display of the video on the display device 510 according to the luminance of the external light. Specifically, the control device 550 controls the display of the 3DCG to adjust the brightness such that the video is not blurred by the light amount in a case where the external light is bright to a certain extent, and to adjust the contrast and the color tone according to the light detected by the sensor unit 521 in a case where the color gamut is changed by the external light. Furthermore, in a case where the contact sensor is provided as the sensor unit 521, the control device 550 controls the display of the 3DCG video such that the image changes according to the stimulus by the contact in, for example, the region where the performer PE has come into contact on the display device 510.

The video captured by the imaging unit 541 is output to the display device 560 via the control device 550. The video displayed on the display device 560 is confirmed by a staff or the like who creates the video using the display system 500.

The illumination device 570 serves as lighting equipment for studio photographing, and mainly emits light to the performer PE. Light irradiation by the illumination device 570 may be adjusted by a staff who creates the video, or may be controlled by the control device 550.

Here, in a case where the display device 510 includes a display unit based on the existing display technology, reflection occurs due to surface reflection of the light of the illumination device 570, which impairs reality of the video. Meanwhile, in a case where the surface of the display unit is matted, the contrast of the display video is lowered due to scattering reflection, which deteriorates the video quality.

In view of the above, by including, in the display device 510, the display unit 511 to which the technology according to the present disclosure is applied, it becomes possible to achieve both suppression of light reflection on the surface of the display unit 511 and maintenance of high contrast, and to improve the video quality while maintaining the reality of the video.

Furthermore, in a case where each of the display units 511 has at least one of flexibility or extensibility, a deformation mechanism 580 that enables deformation of the plurality of display units 511 and the entire display device 510 may be provided.

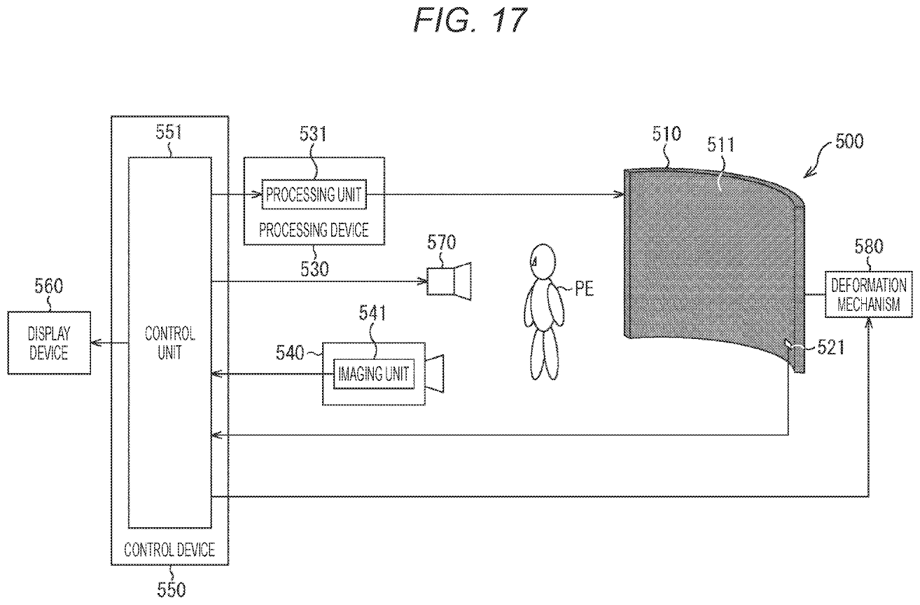

The deformation mechanism 580 supports the plurality of display units 511 from the opposite side of the display surface, for example. The deformation mechanism 580 changes its shape to deform the entire display device 510 into a cylindrical display shape such that the display surface is on the concave surface side as illustrated in FIG. 17, for example.

The shape of the deformation mechanism 580 may be manually changed by a staff who creates the video, or may be changed under the control of the control device 550.

In a case where the shape of the deformation mechanism 580 is changed under the control of the control device 550, the control device 550 (control unit 551) may change the shape of the deformation mechanism 580 on the basis of the physical quantity detected by the sensor unit 521 provided in the display unit 511.

For example, in a case where the distance sensor is provided as the sensor unit 521, the control device 550 changes the shape of the deformation mechanism 580 on the basis of a positional relationship between the display device 510 and the subject, such as the performer PE, and optical characteristics (depth of field, etc.) of the imaging device 540. For example, as the distance between the display device 510 and the performer PE is shorter, the display device 510 deforms to surround the performer PE, whereby more realistic video may be obtained.

As described above, according to the technology according to the present disclosure, it becomes possible to achieve video representation of higher quality even in the field of virtual production.

The embodiments of the technology according to the present disclosure are not limited to the embodiments described above, and various modifications may be made without departing from the scope of the technology according to the present disclosure.

The effects described herein are merely examples and are not limited, and other effects may be exerted.

Moreover, the technology according to the present disclosure may have the following configurations.
(1)
A display system including:
a display including:
a plurality of light sources; and
a light absorption layer that forms a display surface and absorbs external light applied to the display surface, in which
an opening through which light from the light sources is emitted toward a side of the display surface is formed in the light absorption layer.
(2)
The display system according to (1), in which
the light absorption layer has an uneven structure.
(3)
The display system according to (2), in which
the uneven structure includes a structure that suppresses reflection of the external light.
(4)
The display system according to any one of (1) to (3), in which
the light source forms a pixel including RGB subpixels.
(5)
The display system according to (4), in which
light emission of the subpixels is controlled by at least one of a light emitting diode (LED) element, an organic electro-luminescence (EL) element, or a liquid crystal element.
(6)
The display system according to (4) or (5), in which
the opening is formed such that one opening is formed for one of the light sources.
(7)
The display system according to (4) or (5), in which
the opening is formed such that one opening is formed for two or more of the light sources.
(8)
The display system according to (4) or (5), in which
a plurality of the openings is formed for one of the light sources.
(9)
The display system according to any one of (1) to (8), in which
the display has at least one of flexibility or extensibility.
(10)
The display system according to (9), in which
the display further includes a flexible substrate including a non-stretchable portion and a stretchable portion on a side opposite to the side of the display surface of the light absorption layer, and
the light source is arranged on the non-stretchable portion of the flexible substrate.
(11)
The display system according to (10), in which
the display further includes a planarization layer formed to cover a surface of the flexible substrate on which the light source is arranged and having at least one of the flexibility or the extensibility.
(12)
The display system according to (11), in which
the planarization layer has a non-adhesive region not directly adhered to the flexible substrate in a portion corresponding to the stretchable portion.
(13)
The display system according to (11), in which
a space is formed between the portion corresponding to the stretchable portion of the planarization layer and the flexible substrate.
(14)
The display system according to any one of (1) to (13), in which
the display includes a sensor unit that detects a physical quantity on the display surface instead of any of the plurality of light sources.
(15)
The display system according to (14), in which
the sensor unit includes at least one of a distance sensor that detects a distance from an object located on the side of the display surface of the display, a luminance sensor that detects luminance of the external light, or a contact sensor that detects contact with the display surface.
(16)
The display system according to any one of (1) to (15), further including:
a plurality of the displays; and
a processing unit that executes display processing of an image on the plurality of displays.
(17)
The display system according to (16), further including
an imaging unit that captures the image displayed on the plurality of displays.
(18)
The display system according to (17), further including
a control unit that controls display of the image on the plurality of displays according to an imaging range of the imaging unit.
(19)
The display system according to (18), further including:
a display device including the plurality of displays;
a processing device including the processing unit;
an imaging device including the imaging unit; and
a control device including the control unit.
(20)
The display system according to any one of (16) to (19), further including
a deformation mechanism that enables deformation of a display device in which the plurality of displays is arranged, in which
the plurality of displays has at least one of flexibility or extensibility.

### REFERENCE SIGNS LIST

11 Display system
33 Video wall
51 Display unit
210 Light source substrate
220 Light absorption layer
221 Opening
230 Wiring substrate
231 Light emitting element
240 Planarization layer
300a Cylindrical display
300b Spherical display
320 Display unit
320S Non-stretchable portion
320N Stretchable portion
340 Flexible substrate
341 Non-stretchable portion
342 Stretchable portion
350 Planarization layer
360 Non-adhesive layer
370 Space
500 Display system
510 Display device
511 Display unit
521 Sensor unit
530 Processing device
531 Processing unit
540 Imaging device
541 Imaging unit
550 Control device
551 Control unit
580 Deformation mechanism

1. A display system comprising:
a display including:
a plurality of light sources; and
a light absorption layer that forms a display surface and absorbs external light applied to the display surface, wherein
an opening through which light from the light sources is emitted toward a side of the display surface is formed in the light absorption layer.

2. The display system according to claim 1, wherein
the light absorption layer has an uneven structure.

3. The display system according to claim 2, wherein
the uneven structure includes a structure that suppresses reflection of the external light.

4. The display system according to claim 1, wherein
the light source forms a pixel including RGB subpixels.

5. The display system according to claim 4, wherein
light emission of the subpixels is controlled by at least one of a light emitting diode (LED) element, an organic electro-luminescence (EL) element, or a liquid crystal element.

6. The display system according to claim 4, wherein
the opening is formed such that one opening is formed for one of the light sources.

7. The display system according to claim 4, wherein
the opening is formed such that one opening is formed for two or more of the light sources.

8. The display system according to claim 4, wherein
a plurality of the openings is formed for one of the light sources.

9. The display system according to claim 1, wherein
the display has at least one of flexibility or extensibility.

10. The display system according to claim 9, wherein
the display further includes a flexible substrate including a non-stretchable portion and a stretchable portion on a side opposite to the side of the display surface of the light absorption layer, and
the light source is arranged on the non-stretchable portion of the flexible substrate.

11. The display system according to claim 10, wherein
the display further includes a planarization layer formed to cover a surface of the flexible substrate on which the light source is arranged and having at least one of the flexibility or the extensibility.

12. The display system according to claim 11, wherein
the planarization layer has a non-adhesive region not directly adhered to the flexible substrate in a portion corresponding to the stretchable portion.

13. The display system according to claim 11, wherein
a space is formed between the portion corresponding to the stretchable portion of the planarization layer and the flexible substrate.

14. The display system according to claim 1, wherein
the display includes a sensor unit that detects a physical quantity on the display surface instead of any of a plurality of the light sources.

15. The display system according to claim 14, wherein
the sensor unit includes at least one of a distance sensor that detects a distance from an object located on the side of the display surface of the display, a luminance sensor that detects luminance of the external light, or a contact sensor that detects contact with the display surface.

16. The display system according to claim 1, further comprising:
a plurality of the displays; and
a processing unit that executes display processing of an image on a plurality of the displays.

17. The display system according to claim 16, further comprising
an imaging unit that captures the image displayed on a plurality of the displays.

18. The display system according to claim 17, further comprising
a control unit that controls display of the image on a plurality of the displays according to an imaging range of the imaging unit.

19. The display system according to claim 18, further comprising:
a display device including a plurality of the displays;
a processing device including the processing unit;
an imaging device including the imaging unit; and
a control device including the control unit.

20. The display system according to claim 16, further comprising
a deformation mechanism that enables deformation of a display device in which a plurality of the displays is arranged, wherein
a plurality of the displays has at least one of flexibility or extensibility.
